(19) United States
(12) Patent Application Publication
(10) Pub. No.: US 2009/0148980 A1
(43) Pub. Date: Jun. 11, 2009

(54) METHOD FOR FORMING PHASE-CHANGE MEMORY ELEMENT

(75) Inventor: Tu-Hao Yu, HSINCHU CITY (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTONICS CORP., HSINCHU (TW)

(21) Appl. No.: 12/189,090

(22) Filed: Aug. 8, 2008

(30) Foreign Application Priority Data
Dec. 11, 2007 (TW) TW96147195

(51) Int. Cl. H01L 45/00

(52) U.S. Cl. 438/102; 257/E45.002

(57) ABSTRACT

A method for forming a phase-change memory element. The method includes providing a substrate with an electrode formed thereon; sequentially forming a conductive layer and a first dielectric layer on the substrate; forming a patterned photoresist layer on the first dielectric layer; subjecting the patterned photoresist layer to a trimming process, remaining a photoresist pillar; etching the first dielectric layer with the photoresist pillar as etching mask, remaining a dielectric pillar; comformally forming a first phase-change material layer on the conductive layer and the dielectric pillar to cover the top surface and side walls of the dielectric pillar; forming a second dielectric layer to cover the first phase-change material layer; subjecting to the second dielectric layer and the first phase-change material layer to a planarization until exposing the top surface of the dielectric pillar; and forming a second phase-change material layer on the second dielectric layer.

### CROSS REFERENCE TO RELATED APPLICATIONS

This application is based upon and claims the benefit of priority from the prior Taiwan Patent Application No. 96147195, filed on Dec. 11, 2007, the entire contents of which are incorporated herein by reference.

### BACKGROUND OF THE INVENTION

1. Field of the Invention

The invention relates to a method for forming a memory element, and more particularly to a method for forming a phase-change memory element.

2. Description of the Related Art

Electronic devices use different types of memories, such as DRAM, SRAM and flash memory or a combination based on application requirements, operating speed, memory size and cost considerations of the devices. Current new developments in the memory technology field include FeRAM, MRAM and phase-change memory. Among these alternative memories, phase-change memory is most likely to be mass-produced in the near future.

Phase-change memory is targeted for applications currently utilizing flash non-volatile memory. Such applications are typically mobile devices which require low power consumption, and hence, minimal programming currents. A phase-change memory cell is designed with several goals in mind: low programming current, higher reliability (including electromigration risk), smaller cell size, and faster phase transformation speed. These requirements often set contradictory requirements on feature size, but a careful choice and arrangement of materials used for the components can often widen the tolerance.

The most straightforward way to reduce the programming current is to reduce the heating area. A benefit of this strategy is simultaneous reduction of cell size. However, reducing the area results in higher cell resistance, which increases required driving voltage. All other considerations being the same, the amount of Joule heating is conserved, meaning the operating voltage is inversely proportional to the programming current. This is clearly not desirable. Reducing heating area does not necessarily improve other performance features. Phase transformation speed requires good thermal uniformity within the active regions of the cell.

FIGS. 1a to 1d show a method for forming a conventional phase-change memory element 50 with a dielectric via hole 18 formed by photolithography process, comprising the following steps. First, a substrate 10 is provided, wherein the substrate comprises a bottom electrode 12. Next, a connective layer 14 is formed on the substrate 10 to electrically contact to the bottom electrode 12. Next, a dielectric layer 16 with a dielectric via hole 18 formed by photolithography process is formed on the connective layer 14. Finally, a phase-change material layer 20 is formed on the dielectric layer 16 to fill the dielectric via hole 18. The above process can reduce the size of the dielectric via hole 18 via photolithography process, resulting in reduced contact area between the phase-change material layer 20 and the connective layer 14.

However, the size of the dielectric via hole 18 cannot further be reduced due to the resolution limit of a photolithography process. Furthermore, a void 22 would be occurred when a phase-change material layer 20 filling into the dielectric via hole 18 due to the worse gap filling ability of the phase-change material, referring to FIG. 2, resulting in degrading the performance.

A method is also disclosed to solve the above problem. Referring to FIG. 3a, a bottom electrode 102 is formed on a substrate 100. In FIG. 3b, a dielectric layer 104 is formed on the bottom electrode 102 and patterned to form an opening 106 thereinto.

Next, referring to FIG. 3c a connective layer 108 is comformally formed into the opening 106, completely covering the sidewalls and the bottom surface of the opening.

Next, referring to FIG. 3d, a dielectric layer 110 is blanketly formed on the connective layer 108 and filled up the opening 106. Referring to FIG. 3e, the connective layer 108 and the dielectric layer 110 are subjected to a planarization to expose the top surface of the dielectric layer 104a, forming a cup-shaped conductive layer 108a. The remained dielectric layer 110a covers the sidewalls and the bottom surface of the cup-shaped conductive layer 108a and exposes the top surface of the cup-shaped conductive layer 108a. Referring to FIG. 3f, a phase-change material layer 112 is formed on the above structure to electrically contact to the top surface of the cup-shaped conductive layer 108a.

It should be noted that, in the above process, the connective layer 108 and the dielectric layer 110 are sequentially formed into the opening 106, rather than filling the phase-change material layer into the opening directly as disclosed in process of FIG. 1a to 1d. However, the size of the opening is still limited by the resolution limit of photolithography process and voids would be still occurred due to the worse gap filling ability of the phase-change material.

Therefore, it is necessary to develop a phase-change memory to solve the previously described problems.

### BRIEF SUMMARY OF THE INVENTION

An exemplary embodiment a method for forming a phase-change memory element comprises providing a substrate with an electrode formed thereon; sequentially forming a conductive layer and a first dielectric layer on the substrate, wherein the conductive layer is electrically contacted to the electrode; forming a patterned photoresist layer on the first dielectric layer; subjecting the patterned photoresist layer to a trimming process, remaining a photoresist pillar; etching the first dielectric layer with the photoresist pillar as etching mask, remaining a dielectric pillar; comformally forming a first phase-change material layer on the conductive layer and the dielectric pillar to cover the top surface and side walls of the dielectric pillar; forming a second dielectric layer to cover the first phase-change material layer; subjecting to the second dielectric layer and the first phase-change material layer to a planarization until exposing the top surface of the dielectric pillar; and forming a second phase-change material layer on the second dielectric layer, wherein the second phase-change material layer is electrically contacted to the first phase-change material layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1a to 1d are cross sections of a method for fabricating conventional phase-change memory element.

FIG. 2 is a cross section showing the drawback of the method for fabricating conventional phase-change memory element in FIGS. 1a to 1d.

FIGS. 3a-3f are cross sections of a method for fabricating a phase-change memory element according to another conventional phase-change memory element.

FIGS. 4a-4g are cross sections of a method for fabricating a phase-change memory element according to an embodiment of the invention.

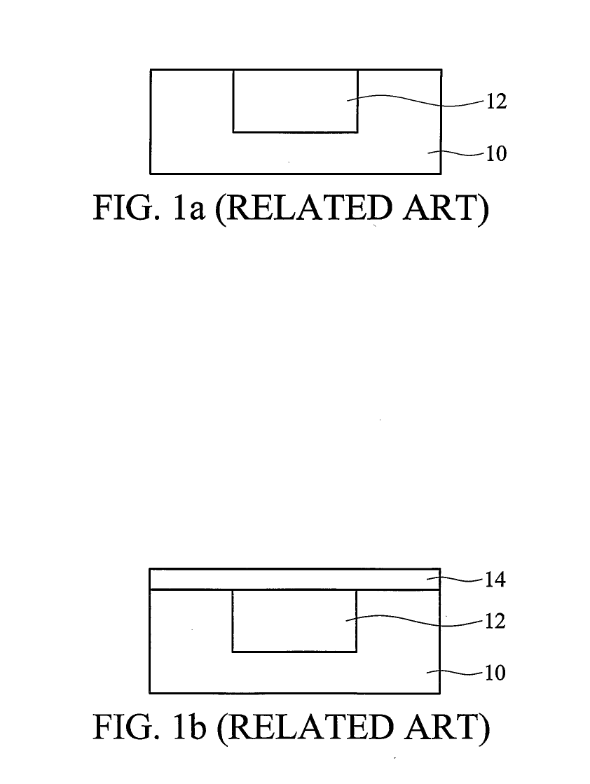

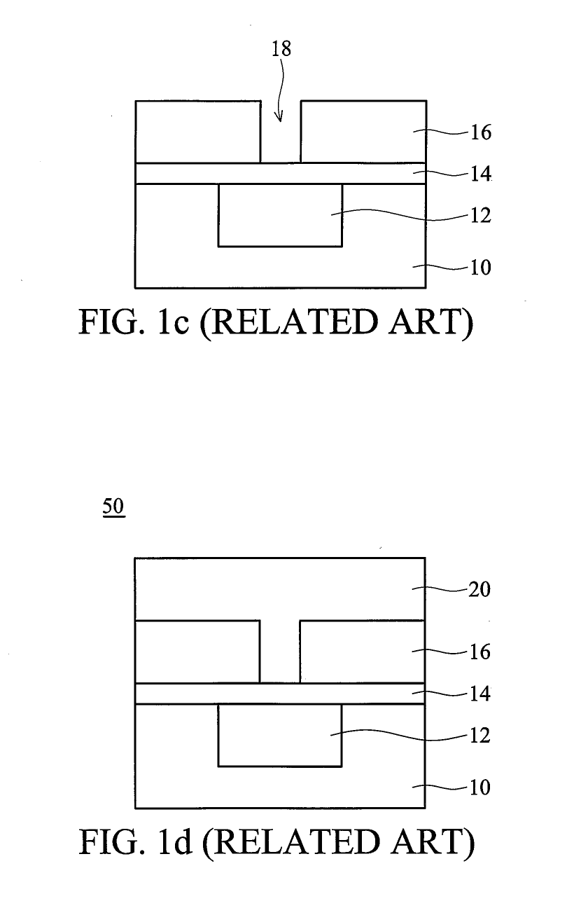

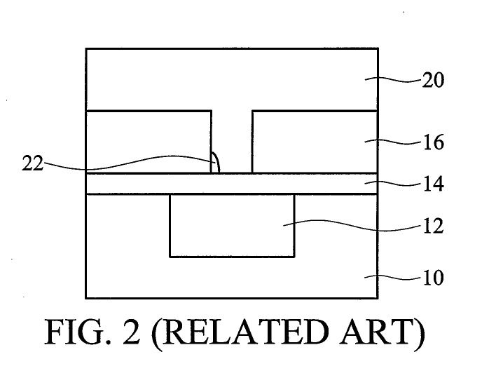

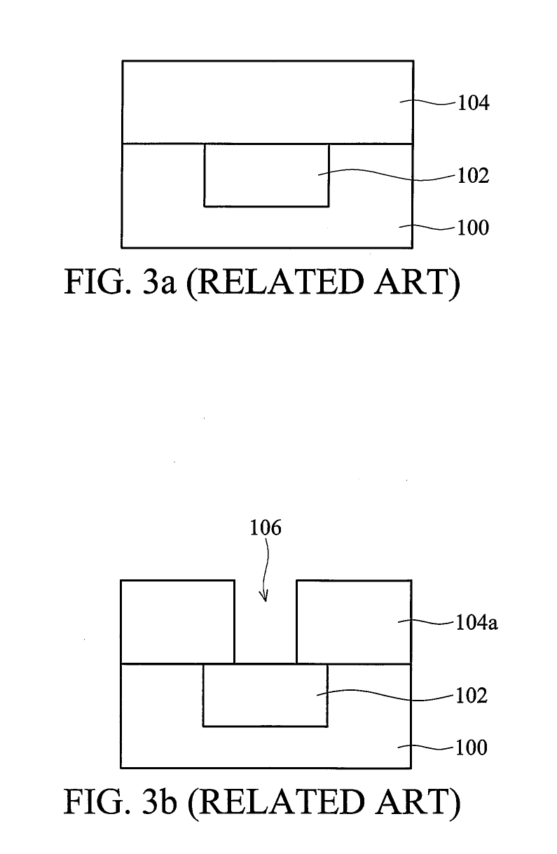

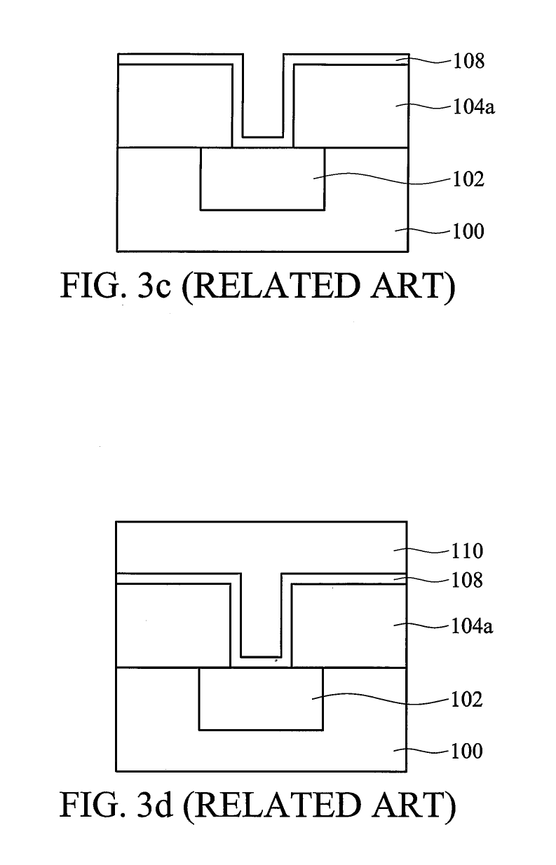

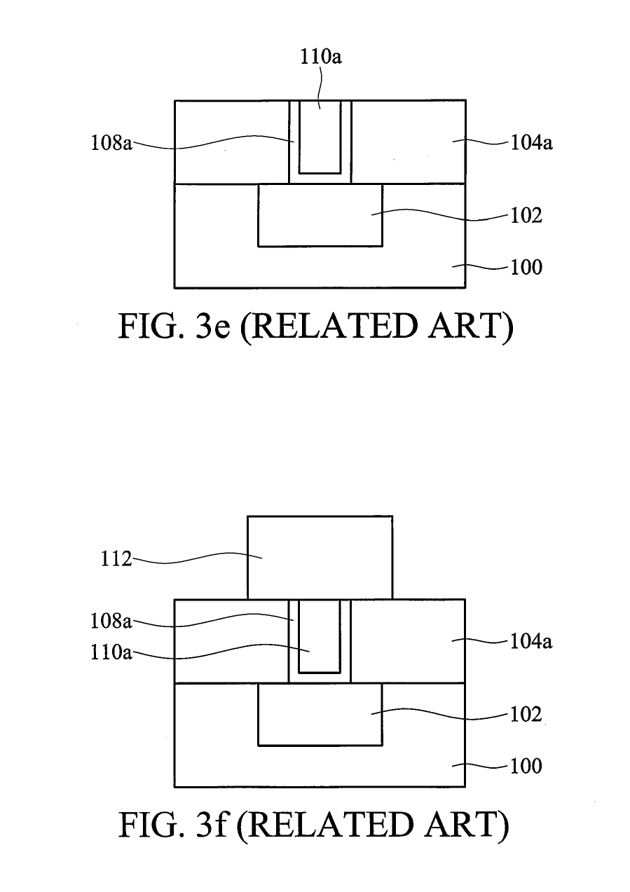

### DETAILED DESCRIPTION OF THE INVENTION

The invention provides a method for forming phase-change memory elements without forming high width-height ratio opening by photolithography process and filling phase-change material layer into the opening, rather than conventional method for forming phase-change memory elements. Therefore, the disclosed method for forming phase-change memory element allows reduction of both process complexity and cost, and is compatible with various processes.

The following description is of the best-contemplated mode of carrying out the invention. This description is made for the purpose of illustrating the general principles of the invention and should not be taken in a limiting sense. The scope of the invention is best determined by reference to the appended claims.

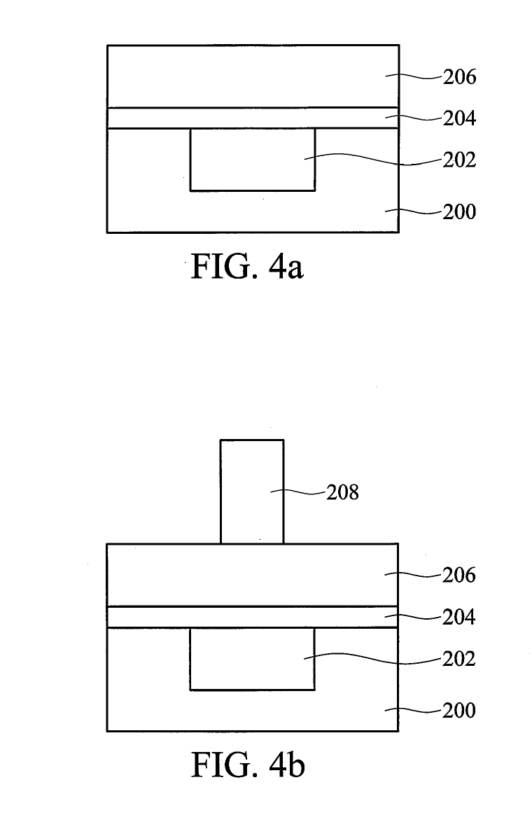

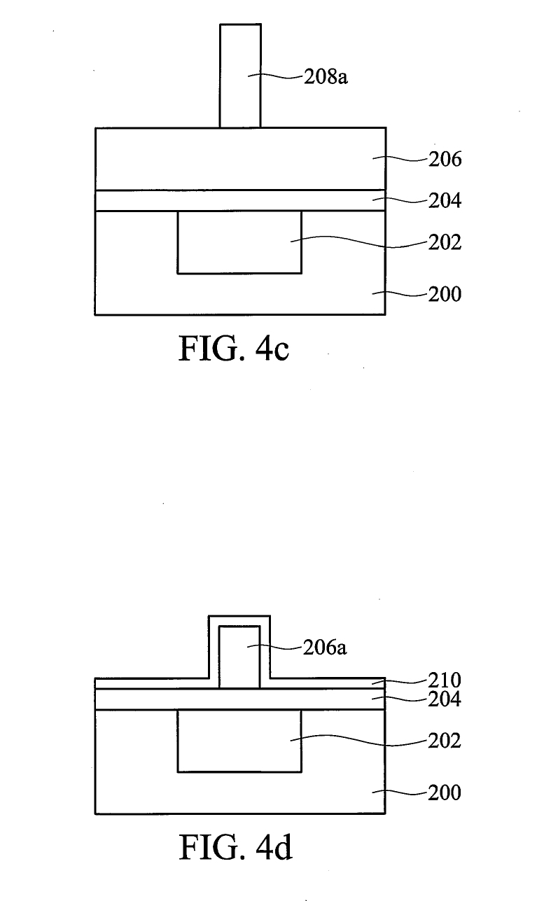

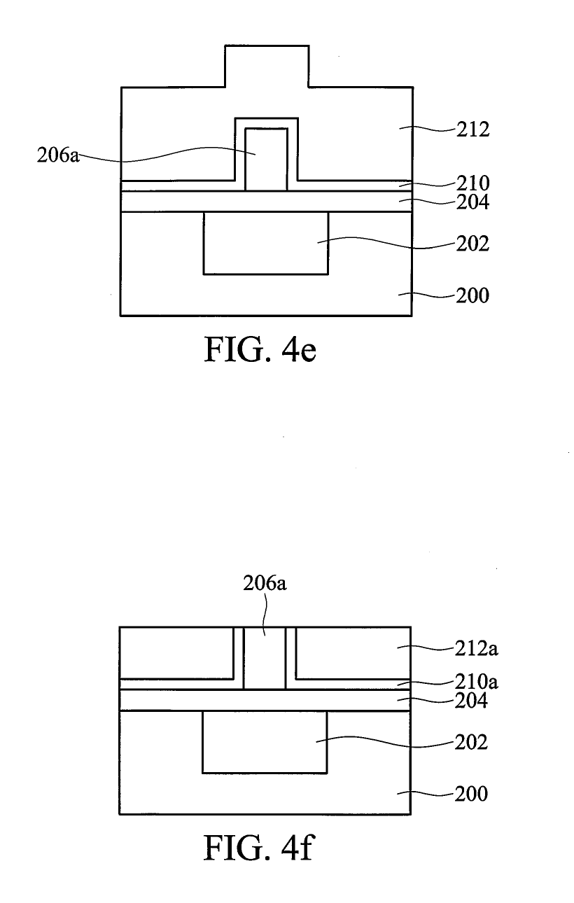

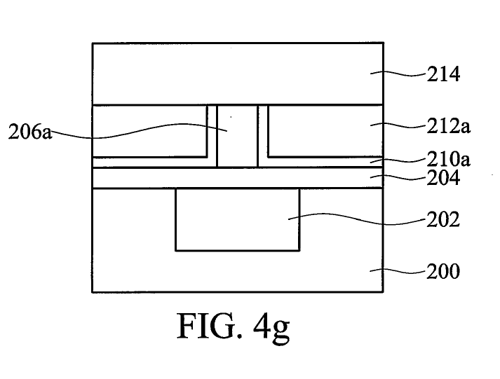

First, referring to FIG. 4a, a substrate 200 with an electrode 202 is provided, and a conductive layer 204 and a first dielectric layer 206 are sequentially formed on the substrate, wherein the conductive layer 204 is electrically contacted to the electrode 202.

The substrate 200 can be a substrate comprising a complementary metal oxide semiconductor (CMOS) circuit, isolation structure, diode, or capacitor. The accompanying drawings show the substrate 200 in a plain rectangle in order to simplify the illustration. Suitable material for the electrode 202 and the conductive layer 204, can be the same or different, and, for example, is TaN, W, TiN, or TiW. The first dielectric layer 206 can be conventional dielectric material, such as silicon oxide or silicon nitride.

Next, referring to FIG. 4b, a patterned photoresist layer 208 is formed on the first dielectric layer 206. Next, the patterned photoresist layer 208 is subjected to a trimming process to form a photoresist pillar 208a with a cross-section diameter of not more than 75 nm, referring to FIG. 4c. It should be noted that, the photoresist pillar 208a is located directly over the electrode 202. The trimming process is not limited to certain process, and can be dry trimming process (such as plasma trimming process) or solution trimming process.

Next, referring to FIG. 4d, the first dielectric layer 206 is etched with the photoresist pillar 208a serving as etching mask to form a dielectric pillar 206a. Next, a first phase-change material layer 210 is conformally formed on the conductive layer 204 and the dielectric pillar 206a, wherein the top surface and side walls of the dielectric pillar 206a is covered by the first phase-change material layer 210. The dielectric pillar 206a has a cross-section diameter of not more than 75 nm. The first phase-change material layer 210 can comprise In, Ge, Sb, Te or combinations thereof, such as GeSbTe or InGeSbTe. Further, the first phase-change material layer 210 has a thickness of between 5˜40 nm.

Next, referring to FIG. 4e, a second dielectric layer 212 is formed to cover the first phase-change material layer 210. The second dielectric layer 212 can be conventional dielectric material, such as silicon oxide or silicon nitride. In the invention, the method for forming a phase-change memory element does not comprise filling the first phase-change material layer into a concave (opening), and there are no voids between the obtained first phase-change material layer and the dielectric layer.

Next, referring to FIG. 4f, the second dielectric layer 212 and the first phase-change material layer 210 are subjected to a planarization until exposing the top surface of the dielectric pillar 206a. The planarization comprises a chemical mechanical polishing. In this step, the remained first phase-change material layer 210a is surrounded and covered the side walls of the dielectric pillar 206a.

Finally, referring to FIG. 4g, a second phase-change material layer 214 is formed on the remained second dielectric layer 212a, wherein the second phase-change material layer 214 is electrically contacted to the remained first phase-change material layer 210a. The second phase-change material layer 214 can comprise In, Ge, Sb, Te or combinations thereof, such as GeSbTe or InGeSbTe.

The invention provides a method for forming phase-change memory element with different steps in comparison with conventional method. The method of the invention avoids forming high width-height ratio opening by photolithography process and filling phase-change material layer into the opening. According to the method of the invention, the photoresist island (pillar) is formed by wide-area etching (rather than thin-area etching to form an opening), resulting in preventing from the occurrence of etch stop. The photoresist island (pillar) can be further subjected to a trimming process for reducing the diameter thereof. A feature of the invention, after formation of the dielectric pillar, a phase-change material layer (or heating electrode) is conformally formed to cover the dielectric pillar and a dielectric layer is subsequently formed on the phase-change material layer. After chemical mechanical polishing, the remained phase-change material layer has a collar structure, covering the side walls of the dielectric pillar. The top surface of the remained phase-change material layer is electrically contacted to a heating electrode (such as phase-change material layer).

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a phase-change memory element, comprising:
providing a substrate with an electrode formed thereon;
sequentially forming a conductive layer and a first dielectric layer on the substrate, wherein the conductive layer is electrically contacted to the electrode;
forming a patterned photoresist layer on the first dielectric layer;
subjecting the patterned photoresist layer to a trimming process, remaining a photoresist pillar;
etching the first dielectric layer with the photoresist pillar as etching mask, remaining a dielectric pillar;
comformally forming a first phase-change material layer on the conductive layer and the dielectric pillar to cover the top surface and side walls of the dielectric pillar;
forming a second dielectric layer to cover the first phase-change material layer;
subjecting to the second dielectric layer and the first phase-change material layer to a planarization until exposing the top surface of the dielectric pillar; and
forming a second phase-change material layer on the second dielectric layer, wherein the second phase-change material layer is electrically contacted to the first phase-change material layer.

2. The method as claimed in claim 1, wherein the first and second phase-change material layer comprises chalcogenide.

3. The method as claimed in claim 1, wherein the conductive layer comprises TaN, W, TiN, or TiW.

4. The method as claimed in claim 1, wherein the trimming process comprises dry trimming process or solvent trimming process.

5. The method as claimed in claim 1, wherein the first phase-change material layer has a thickness of between 5˜40 nm.

6. The method as claimed in claim 1, wherein the dielectric pillar has a cross-section diameter not more than 75 nm.

7. The method as claimed in claim 1, wherein the planarization comprises a chemical mechanical polishing.

8. The method as claimed in claim 1, wherein the method does not comprise filling the first phase-change material layer into a concave.

9. The method as claimed in claim 8, wherein the formed first phase-change material layer is void-free.
